(19) United States
(12) Patent Application Publication
(10) Pub. No.: US 2008/0211568 A1
(43) Pub. Date: Sep. 4, 2008

(54) MuGFET POWER SWITCH

(75) Inventors: Christian Pacha, Muenchen (DE); Florian Bauer, Muenchen (DE); Jorg Berthold, Muenchen (DE); Georg Georgakos, Erding (DE)

Correspondence Address: SCHWEGMAN, LUNDBERG & WOESSNER / INFINEON, P.O. BOX 2938, MINNEAPOLIS, MN, 55402, US

(73) Assignee: INFINEON TECHNOLOGIES AG, MUNICH (DE)

(21) Appl. No.: 11/680,741

(22) Filed: Mar. 1, 2007

(51) Int. Cl. H03K 17/687

(52) U.S. Cl. 327/429; 327/427

(57) ABSTRACT

A multi-gate field effect transistor power switch is used to selectively couple a circuit to a supply voltage. In various embodiments, both n and p-type multi-gate field effect transistor power switches may be used to couple sub-circuits of varying granularity to different voltage supplies.

### BACKGROUND

Integrated circuits (ICs) contain many devices such as transistors, diodes and others, which may be arranged to perform different functions. Devices may be combined to form logic circuits, modules, function blocks, processor stages, etc. Commonly, many of the devices are not used for various periods of time, but still consume power at least because of leakage currents.

Leakage currents are a significant challenge for sub-100 nm CMOS (Complementary Metal-Oxide Semiconductor) technologies. To reduce leakage currents during standby modes, when selected portions of circuits are not being utilized, modern CMOS integrated circuits use CMOS power switches to disconnect them from on-chip power supplies. Power switches are an elementary part of leakage reduction strategies and are applied in a broad range of products, such as baseband-ICs, microcontrollers, DSPs (digital signal processors), memories and microprocessors.

In conventional planar bulk CMOS technologies, typically only one type of field effect transistor (FET), either an nFET or pFET type of power switch is used to implement power switches. Due to their better current driving abilities, nFET type power switches are preferred since they provide the same low-resistive connection of virtual power supply lines to unswitched power supply lines as pFET type power switches at a much smaller transistor width and hence have lower leakage current. However, nFET type power switches require a triple well isolation in order to isolate the floating body potential referred to as VSSBULK (voltage source bulk) within a deactivated circuit block from the remaining parts of the chip. On the other hand, if pFET type power switches are used, a natural isolation is provided due to the separation of n-wells but result in an area overhead of approximately twice compared to nFET type power switches is generated.

These tradeoffs require a designer to choose between low process complexity and larger area in the case of pFET type power switches and smaller area and increased process complexity for nFET type power switches. Both alternatives are suboptimal.

### BRIEF DESCRIPTION OF THE DRAWINGS

FIGS. 1A, 1B and 1C illustrate MuGFET (multi-gate field effect transistor) power switches that selectively isolate circuits from various voltages according to an example embodiment.

FIG. 2 is a block diagram of an example MuGFET power switch.

FIGS. 3A, 3B and 3C are block diagram examples of circuits having sub-circuits with MuGFET power switches that selectively isolate the sub-circuits from different voltage levels according to an example embodiment.

FIG. 4 illustrates multiple MuGFET power switches that selectively isolate a circuit from ground or a power source according to an example embodiment.

FIG. 5 illustrates the use of MuGFET power switches to selectively isolate a static random access memory (SRAM) core and periphery access circuitry from different voltage levels according to an example embodiment.

FIG. 6 illustrates the use of MuGFET power switches to selectively isolate selected stages of a microprocessor pipeline from different voltage levels according to an example embodiment.

FIG. 7 illustrates the use of MuGFET power switches to selectively isolate a microprocessor and a digital signal processor (DSP) from different voltage levels according to an example embodiment.

FIG. 8 illustrates arrays of power switches selectively coupled to circuits according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

MuGFET (multi-gate field effect transistor) power switches may be used to selectively isolate or disconnect circuits from various voltages, such as ground or supply voltages. Several example circuits, including sub-circuits are shown and described. One or more arrays of power switches are also described and may be formed with the same or different current characteristics to facilitate different operating levels and different timing for reactivating sub-circuits.

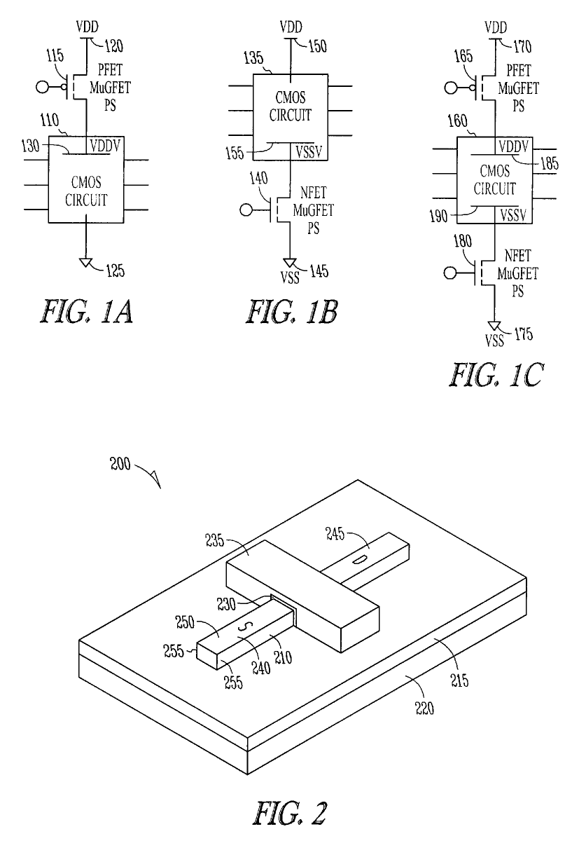

FIGS. 1A, 1B and 1C are circuit diagrams of MuGFET power switches that selectively isolate circuits from various voltages according to an example embodiment. FIG. 1A includes a complementary metal oxide semiconductor (CMOS) circuit 110 that is supported by a substrate which is not shown. A p-type MuGFET power switch 115 selectively couples circuit 110 to a voltage supply 120, which in one embodiment is a positive high voltage such as VDD. MuGFET power switch 115 may be turned on by application of a low voltage to its gate, and may be turned off by application of a high voltage. The magnitudes of the voltages depend on the transistor characteristics. In some embodiments, the MuGFET power switch 115 may be partially turned on to provide for operation of the circuit at a reduced voltage and hence reduced power level.

The circuit 110 is also coupled to a further voltage supply 125, which in one embodiment is ground or VSS. In one embodiment, a small voltage, ΔV, drop may occur across power switch 115, such that a virtual voltage 130, referred to as VDDV in one embodiment, is provided to power the circuit 110. This voltage drop may be caused by an ohmic resistance of the MuGFET power switch 115. In one embodiment, the circuit 110 includes MuGFET transistors.

In FIG. 1B, a CMOS circuit 135 is supported by a substrate which is not shown. An n-type MuGFET 140 selectively couples circuit 135 to a voltage supply 145, which in one embodiment is a low voltage or ground such as VSS. The circuit 135 is also coupled to a further voltage supply 150, which in one embodiment is a positive voltage or VDD. In one embodiment, a small voltage drop, ΔV, may occur across power switch 140, such that a virtual voltage 155, referred to as VSSV in one embodiment, is provided to power the circuit 110. In one embodiment, the circuit 110 includes MuGFET transistors.

FIG. 1C includes a complementary metal oxide semiconductor (CMOS) circuit 160 that is supported by a substrate which is not shown. A p-type MuGFET 165 selectively couples circuit 160 to a voltage supply 170, which in one embodiment is a positive high voltage such as VDD. The circuit 160 is also coupled to a further voltage supply 175, which in one embodiment is ground or VSS via an n-type MuGFET power switch 180. In one embodiment, a small voltage drops may occur across the power switches 165 and 180, such that virtual voltages 185 and 190, referred to respectively as VDDV and VSSV in one embodiment, is provided to power the circuit 160. Circuit 160 may be selectively isolated from one or both of the supplies in various embodiments. In one embodiment, the circuit 160 includes MuGFET transistors.

As described above with respect to circuit 110, the MuGFET power switches may be used to selectively isolate the circuits from various voltage supplies, or may be partially turned on to provide for operation of the circuit at a reduced voltage and hence reduced power level. The use of MuGFET power switches may provide for excellent isolation of the circuits due to their formation on a buried oxide layer on the substrate and no bulk contact. Other potential benefits that may be provided by the use of MuGFET power switches are fast turn on times and low substrate area requirements. Both n-type and p-type MuGFET power switches may have similar drive currents. This symmetry provides an additional degree of freedom for circuit designers since leakage current reduction is fairly independent of the type of MuGFET power switch used. Designs may be implemented in a flexible manner with both n-type and p-type types of MuGFET power switches.

FIG. 2 is a block diagram of an example MuGFET power switch 200. Transistor 200 may be a single fin n or p-type transistor 200 and has a body 210, also referred to as a fin 210. The fin may be formed on an insulating surface 215 of a substrate 220. The insulating surface may be a buried oxide or other insulating layer 210 over a silicon or other semiconductor substrate 220. Electrical isolation of the fin may also be provided by a space-charge region if the fins are formed on a bulk silicon substrate. A gate dielectric 230 is formed over the top and on the sides of the semiconductor fin 210. A gate electrode 235 is formed over the top and on the sides of the gate dielectric 230 and may include a metal layer. A source 240 and drain 245 regions may be formed in the semiconductor fin 210 on either side of the gate electrode, and may be laterally expanded to be significantly larger than the fin 210 under the gate electrode 235 in various embodiments.

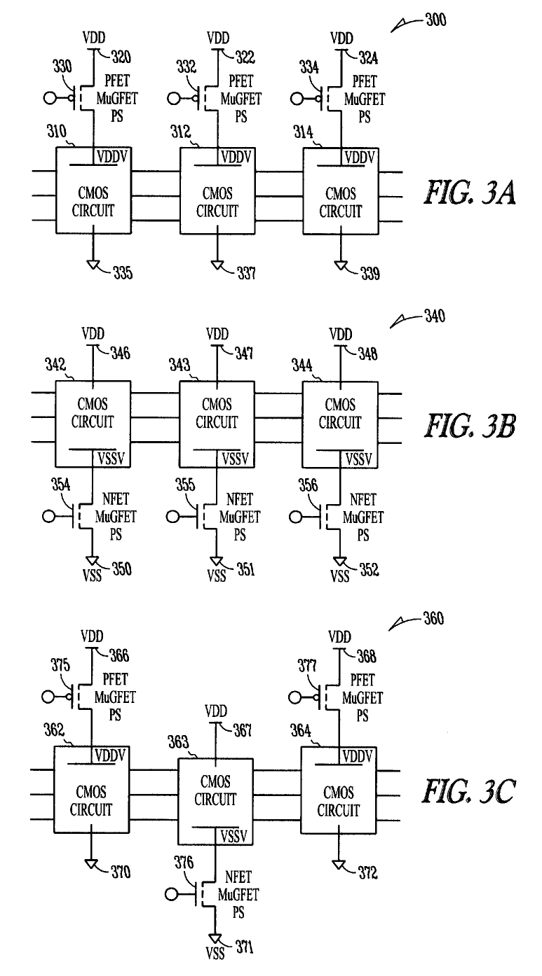

FIGS. 3A, 3B and 3C are block diagram examples of circuits having sub-circuits with MuGFET power switches that selectively isolate the sub-circuits from different voltage levels according to an example embodiment.

FIG. 3A is a circuit block diagram of a circuit 300 having three sub-circuits 310, 312 and 314 coupled to each other by one or more electrical connections. Each sub-circuit 310, 312 and 314 is coupled to respective supply voltages 320, 322 and 324, such as VDD, by respective p-type MuGFET power switches 330, 332 and 334. Sub-circuits 310, 312 and 314 are also respectively coupled to a supply voltage 335, 337 and 339 respectively, such as for example ground or VSS.

Each power switch may result in a drop of ΔV from VDD, further resulting in the sub-circuits being provided a supply voltage of VDD-ΔV, referred to as a virtual voltage or VDDV as an operating supply voltage for the sub-circuit when the power switches are on. Turning the power switches off results in isolation of the sub-circuits from the supply voltage. In further embodiments, a single power switch may be used for all three sub-circuits. In still further embodiments, the power switches are controlled independently, allowing their corresponding sub-circuits to be activated or deactivated independently and in desired order, such as in a staggered manner. In still further embodiments, the power switch transistors may receive signals at the same time to switch on, but may have different current characteristic designed to provide a desired temporal order of reactivation of sub-circuits that are isolated, off, or partially turned on for power reduction.

FIG. 3B is a circuit block diagram of a circuit 340 having three sub-circuits 342, 343, and 344 coupled to each other by one or more electrical connections. Each sub-circuit 342, 343, and 344 is coupled to respective supply voltages 346, 347 and 348, such as VDD, and is coupled to respectively supply voltages 350, 351 and 352, such as for example ground or VSS, by respective n-type MuGFET power switches 354, 355 and 356.

Each power switch may result in a drop of ΔV from VSS, further resulting in the sub-circuits being provided a supply voltage of VSS+ΔV, referred to as a virtual voltage or VSSV as a ground supply voltage for the sub-circuit when the power switches are on. Turning the power switches off results in isolation of the sub-circuits from this supply voltage, and the sub-circuits float toward the other supply voltage, for example, VDD. In further embodiments, a single power switch may be used for all three sub-circuits. In still further embodiments, the power switches are controlled independently, allowing their corresponding sub-circuits to be turned on or off independently and in desired order, such as in a staggered manner. In still further embodiments, the transistors may receive signals at the same time to switch on, but may have different current characteristic designed to provide a desired temporal order of reactivation of sub-circuits that are isolated, off, or partially turned on for power reduction.

FIG. 3C is a circuit block diagram of a circuit 360 having three sub-circuits 362, 363 and 364 coupled to each other by one or more electrical connections. Two supply voltages, for example VDD and VSS may be coupled to the circuits with various power switches. Contacts for a first supply voltage, such as VDD are shown at 366, 367 and 368. Contacts for a second supply voltage, such as VSS are shown at 370, 371 and 372. In one embodiment, sub-circuit 362 is coupled to supply 366 via a p-type MuGFET power switch 375. Sub-circuit 363 is coupled to supply 371 via an n-type MuGFET power switch 376. Sub-circuit 364 is coupled to supply 368 via a p-type MuGFET power switch 377. In further embodiments, a sub-circuit need not be coupled to a power switch. Further, the power switches to the same supplies may share same gate lines, or may be implemented as a single power switch in various embodiments.

Each power switch may result in a difference of ΔV from respective supply voltages, such as for example VDD−ΔV or VSS+ΔV when the power switches are on. Turning the power switches off results in isolation of the sub-circuits from the supply voltage, and they tend to float toward the supply to which they are still coupled. In still further embodiments, the power switches are controlled independently, allowing their corresponding sub-circuits to be turned on or off independently and in desired order, such as in a staggered manner. In still further embodiments, the transistors may receive signals at the same time to switch on, but may have different current characteristic designed to provide a desired temporal order of reactivation of circuits that are isolated, off, or partially turned on for power reduction.

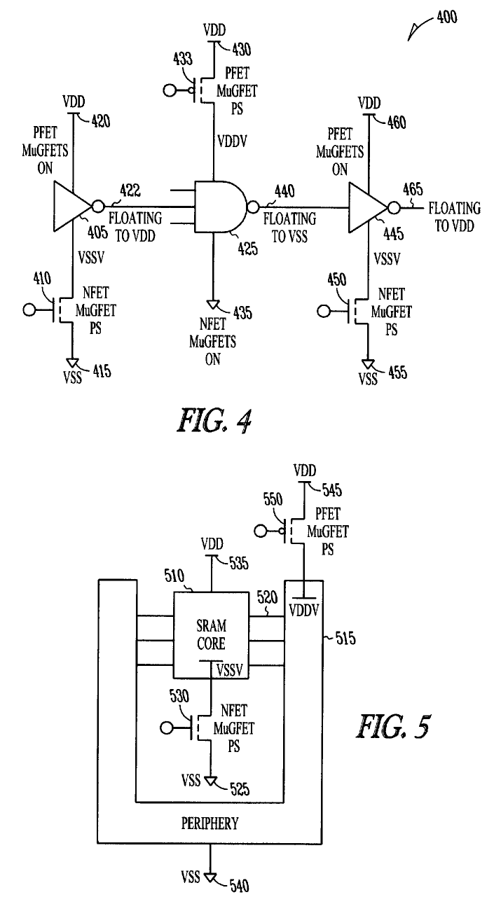

FIG. 4 illustrates multiple MuGFET power switches that selectively isolate individual devices of a circuit 400 from various supplies such as ground or a power source according to an example embodiment. In one example, circuit 400 includes a first inverter 405 coupled via a first n-type MuGFET power switch 410 to ground or VSS 415. The inverter 405 is also coupled to supply, VDD 420. An output 422 of the first inverter 405 floats to VDD 420 when the power switch 410 is off. Output 422 is coupled to a not AND (NAND) gate 425, which is coupled to supply, VDD at 430 via a second p-type MuGFET power switch 433. NAND gate 425 is also coupled to VSS 435.

When second power switch 433 is off, an output 440 of the NAND gate 425 floats toward VSS. Output 440 is coupled to a second inverter 445, which is coupled to a third n-type MuGFET power switch 450, which in turn is coupled to VSS 455. The second inverter 445 is also coupled to VDD at 460 and has an output 465 that floats to VDD when the third power switch 450 is off.

Circuit 400 illustrates the use of n and p-type MuGFET power switches on individual devices in a circuit, and further illustrates that superior isolating characteristics of the MuGFET power switches enables such discrete device level power control with alternating chains of logic gates or elements connected to different supply voltages. In one embodiment, the logic gates may be selected from CMOS logic gates such as NAND gates, inverter gates, AND gates, OR gates or others. This is a very fine granularity that provides each input gate with a stable and full-swing input during standby or reduced power conditions. It also enables a faster reactivation which avoids intermediate voltage levels at gate inputs. The use of MuGFET power switches may reduce the need for separation between prior CMOS power switches, reducing overall demand for chip real estate. In one embodiment, the elements are formed with MuGFET transistors, further enhancing isolation of the circuits due at least to their formation on an insulating layer.

One motivation for a fine granular use of MuGFET power switches is that it may provide for very fast reactivation. If one million gates share a line, a large charge may be required to reactivate all the devices. With an individual power switch on each gate, or small numbers of gates, the need for a large charge is reduced, and such gates may be reactivated quickly.

FIG. 5 illustrates the use of MuGFET power switches to selectively isolate a static random access memory (SRAM) core 510 and periphery access circuitry 515 from different voltage levels according to an example embodiment. In one embodiment, core 510 is comprised of MuGFET transistor implemented cross coupled inverters with access devices. The access devices are coupled via word lines 520 to the periphery access circuitry 515, which may decode received addresses to activate the word lines 520 to access selected memory elements of the core 510. In further embodiments, the access circuitry 515 may also be formed with MuGFET devices.

In one embodiment, the core 510 is selectively coupled to a supply voltage such as VSS 525 by a n-type MuGFET power switch 530. The core 510 is also coupled to a second supply voltage such as VDD 535. Access circuitry 515 is coupled to VDD 545 via a p-type MuGFET power switch 550 and is coupled to VSS 545. ΔV drops across the power switches result in virtual supply levels being provided to the core 510 and access circuitry 515 in some embodiments. The use of p-type MuGFET power switch 550 to isolate the access circuitry from VDD, causes the word lines 520 to float toward VSS. As long as the n-type MuGFET power switch is active, i.e. couples VSSV to VSS, the content of the memory cells is preserved, as the word lines 520 float to VSS and ensure that the memory cells within array 510 are isolated from bit lines by stable wordline voltages that switches the n-type access devices in the memory cells off. When the n-type MuGFET power switch 530 is off, memory content of the cells is lost as the cells float toward VDD. This power switch granularity level may be thought of as medium granularity, since it is less granular than the individual logic element implementations.

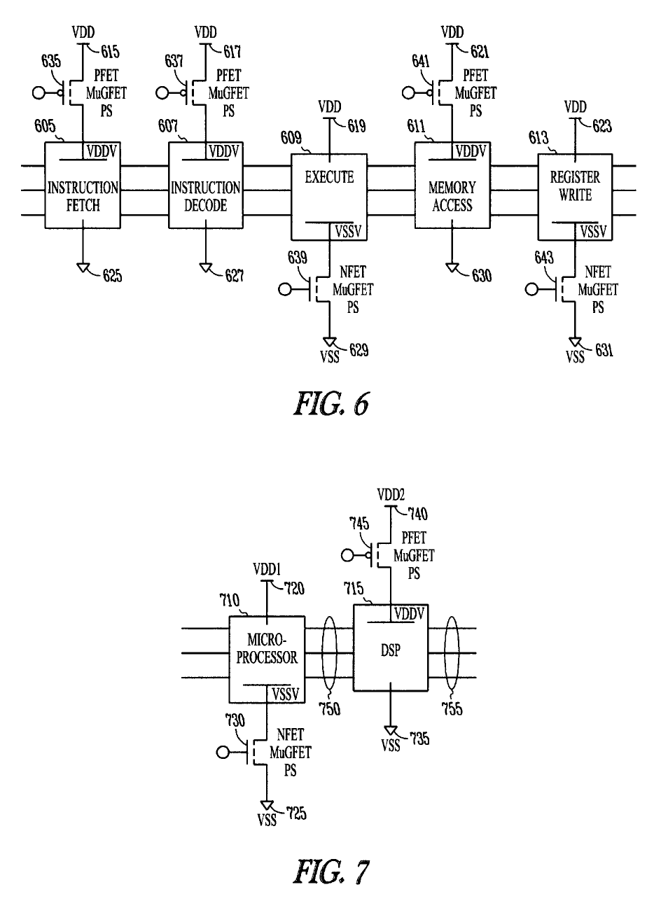

FIG. 6 illustrates a medium granularity use of MuGFET power switches to selectively isolate selected stages of a microprocessor pipeline 600 from different voltage levels according to an example embodiment. In one example pipeline 600, several stages are shown. This is just one example of stages. Different numbers and types of stages are contemplated in further embodiments. An instruction fetch stage 605, instruction decode stage 607, execute state 609, memory access stage 611 and register write stage 613 are shown coupled to each other in pipeline form. In further embodiments, the stages may include multiple units, such as parallel execute units in a stage.

The stages are each coupled to a first supply voltage, such as power supply VDD at 615, 617, 619, 621 and 623 and to a second supply voltage such as a ground or VSS at 625, 627, 629, 630 and 631. In one embodiment, instruction fetch stage 605 is coupled to VDD 615 via a p-type MuGFET power switch 635. Instruction decode stage 607 is coupled to VDD 617 via a p-type MuGFET power switch 637. Execute stage 609 is coupled to VSS 629 via an n-type MuGFET power switch 639. Memory access stage 611 is coupled to VDD 621 via a p-type MuGFET power switch 641. Register write 613 is coupled to VSS 631 via an n-type MuGFET power switch 643. As previously described, each power switch may result in a voltage drop, such as ΔV between the stages and the supplies, resulting in virtual supply voltages being provided to the stages.

Sharing of power switches of the same type is done in one embodiment if the stages are activated and deactivated simultaneously. In some embodiments, it may be desirable to activate and deactivate the different stages at different times. Where there are parallel stages, they may be activated and deactivated together, or independently if desired. The assignment of n type and p type MuGFET power switches may done to optimize or control overall leakage and provide selective reactivation as a function of workload and specific instructions of sub-components. These considerations may result in very different assignments of power switches in various embodiments.

Such power switches may be used in any pipeline system with an arbitrary number of stages. Each stage may have a register on an output. If clock gating is used to save active power in the registers, power supplies to the stages may also be gated. Controlling power switches and clock gating may be done using the same or a derived control signal. Reactivating stages may be done only if the stage is needed for current operations. In still further embodiments, different stages may be deactivated and reactivated during individual clock cycles.

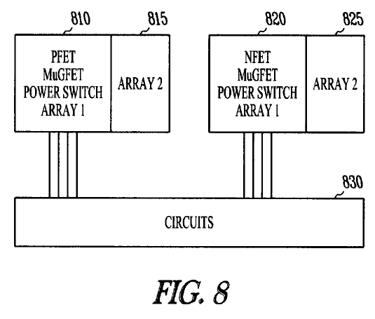

FIG. 7 illustrates the use of MuGFET power switches to selectively isolate a microprocessor 710 and a digital signal processor (DSP) 715 from different voltage levels according to an example embodiment. This type of microprocessor/DSP arrangement may occur in many devices, such as cellular telephones. A similar arrangement on the same granularity level are several identical microprocessors or several microprocessors with different instruction sets. Several digital signal processors (DSPs) or other devices may be used. In some embodiments, homogeneous and heterogeneous arrangements of multiple identical microprocessors and DSPs may be used. In one embodiment, the microprocessor 710 is coupled to VDD at 720 and is coupled to VSS at 725 via a n-type MuGFET power switch 730. DSP 715 is coupled to VSS at 735 and VDD at 740 via a p-type MuGFET power switch 745. With this use of power switches, during a standby mode or other reduced power mode, outputs 750 of microprocessor 719 float toward VDD, and outputs 755 of DSP 715 float toward VSS.

FIG. 8 illustrates arrays of power switches selectively coupled to circuits according to an example embodiment. In one embodiment, an array 810 of p-type MuGFET power switches is provided. At 815, a further array of p-type MuGFET power switches having different turn-on characteristics may be provided.

An array 820 of n-type MuGFET power switches is provided. At 825, a further array of n-type MuGFET power switches having different turn-on characteristics may be provided. Power switches from the various arrays may be coupled to circuits 830 as desired.

Individual power switches may be coupled to different circuit elements, stages, devices, etc., and may provide desired turn-on times to result in such elements turning on at a desired time in relation to other elements without the need for staggering signals to the power switches. Staggering the signals to the power switches may also be done in some embodiments. Ramping of signals and providing different voltages may also result in providing different activation times.

In one embodiment, the arrays of p and n-type MuGFET power switches are physically separated to allow for different processing to provide such different characteristics. For example, different fin heights, different thickness oxide layers over gates, gate lengths and other means of providing MuGFET power switches with different figures of merit may be used.

In further embodiments, distributed power switches or a central block of power switches may be provided to power off different devices.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A circuit comprising:
multiple sub-circuits supported by a substrate;
multiple multi-gate field effect transistor power switches selectively electrically coupling the sub-circuits to different voltages.

2. The circuit of claim 1 wherein p-type multi-gate field effect transistor power switches couple selected sub-circuits to a first voltage, and n-type multi-gate field effect transistor power switches couple selected sub-circuits to a second voltage.

3. The circuit of claim 2 wherein the p-type multi-gate field effect transistor power switches and the n-type multi-gate field effect transistor power switches are alternately used in a sequence of sub-circuits.

4. The circuit of claim 3 wherein some sub-circuits comprise CMOS circuitry.

5. The circuit of claim 3 wherein the first voltage is VDD and the second voltage is VSS.

6. The circuit of claim 3 wherein selected sub-circuits share a multi-gate field effect transistor power switch.

7. The circuit of claim 1 wherein the sub-circuits comprise multiple microprocessors and digital signal processors (DSPs) in a homogeneous or heterogeneous arrangement.

8. A circuit comprising:
a static random access memory core;
periphery access circuitry coupled to the static random access memory core;
a first multi-gate field effect transistor power switch coupled between the static random access memory core and a first voltage; and
a second multi-gate field effect transistor power switch coupled between the periphery access circuitry and a second voltage.

9. The circuit of claim 8 wherein the first voltage comprises VSS and the first power switch is an n-type multi-gate field effect transistor power switch.

10. The circuit of claim 8 wherein the second voltage comprises VDD and the second power switch is a p-type multi-gate field effect transistor power switch.

11. The circuit of claim 8 wherein the first voltage comprises VSS and the first power switch is an n-type multi-gate field effect transistor power switch and wherein the second voltage comprises VDD and the second power switch is a p-type multi-gate field effect transistor power switch.

12. The circuit of claim 8 wherein the static random access memory core comprises multi-gate field effect transistor memory cross coupled inverter cells.

13. A circuit comprising:
a multi-gate field effect transistor based static random access memory core;
multi-gate field effect transistor based periphery access circuitry coupled to the static random access memory core;
a first multi-gate field effect transistor power switch coupling a virtual ground of the static random access memory core to a ground; and
a second multi-gate field effect transistor power switch coupling a virtual supply of the periphery access circuitry to a supply.

14. The circuit of claim 13 wherein the virtual ground has a higher voltage than VSS and wherein the virtual supply has a lower voltage than VDD.

15. The circuit of claim 14 wherein the first power switch is an n-type multi-gate field effect transistor power switch and wherein the second power switch is a p-type multi-gate field effect transistor power switch.

16. The circuit of claim 13 wherein the virtual voltages provide for operation of the circuit under low operating power conditions.

17. A device comprising:
a plurality of microprocessor pipeline stages;
a p-type multi-gate field effect transistor coupling at least one microprocessor pipeline stage to a first voltage; and
an n-type multi-gate field effect transistor coupling at least one microprocessor pipeline stage to a second voltage.

18. The device of claim 17 wherein the stages comprise instruction fetch, instruction decode, execute, memory access and register write.

19. The device of claim 18 wherein multiple stages are coupled to p-type multi-gate field effect transistors and multiple stages are coupled to n-type multi-gate field effect transistors.

20. A method comprising:
forming multiple sub-circuits supported by a substrate;
coupling at least one sub-circuit to a first voltage level by an n-type multi-gate field effect transistor power switch; and
coupling at least one different sub-circuit to a second voltage level by a p-type multi-gate field effect transistor power switch.

21. The method of claim 20 wherein multiple sub-circuits are alternately connected to the different voltage levels by corresponding multi-gate field effect transistor power switches.

22. The method of claim 20 wherein the multi-gate field effect transistor power switches provide virtual voltage levels to the sub-circuits.

23. The method of claim 20 wherein the multi-gate field effect transistor power switches are respectively coupled to a complementary metal oxide semiconductor logic gate of a multi-gate field effect transistor in the sub-circuits.

24. The method of claim 20 wherein the multi-gate field effect transistor power switches are used to selectively power on sub-circuits in a desired temporal order.

25. A method comprising:
forming multiple sub-circuits supported by a substrate;
forming one or more n-type multi-gate field effect transistor power switches;
forming one or more p-type multi-gate field effect transistor power switches;
coupling at least one sub-circuit to a first voltage level by an n-type multi-gate field effect transistor power switch from the one or more n-type multi-gate field effect transistor power switches; and
coupling at least one different sub-circuit to a second voltage level by a p-type multi-gate field effect transistor power switch from the one or more p-type multi-gate field effect transistor power switches.

26. The method of claim 25 wherein forming one or more n-type multi-gate field effect transistor power switches comprises forming such power switches with different performance levels to create different power switches with different turn-on times.

27. The method of claim 25 wherein forming one or more p-type multi-gate field effect transistor power switches comprises forming such power switches with different performance levels to create different power switches with different turn-on times.

28. A circuit comprising:
a complementary metal oxide semiconductor circuit supported by a substrate; and
a multi-gate field effect transistor power switch coupled between the circuit and a voltage supply, wherein the power switch provides selective isolation of the circuit from the supply voltage.

29. The circuit of claim 28 wherein the supply voltage comprises VSS or VDD.
